(19) United States
(12) Patent Application Publication
(10) Pub. No.: US 2006/0184912 A1
(43) Pub. Date: Aug. 17, 2006

(54) Automatic design apparatus for semiconductor integrated circuits, method for automatically designing semiconductor integrated circuits, and computer program product for executing an application for an automatic design apparatus for semiconductor integrated circuits

(75) Inventor: Hiroyuki Takano, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/298,600

(22) Filed: Dec. 12, 2005

(30) Foreign Application Priority Data
Dec. 16, 2004 (JP) 2004-364960

(51) Int. Cl. G06F 17/50; H03K 19/00

(52) U.S. Cl. 716/16; 716/17

(57) ABSTRACT

An automatic design apparatus for semiconductor integrated circuits including a first acquisition module configured to acquire a first function description describing an arrangement of a plurality of data processors, and a second function description describing an arrangement of a plurality of connection selectors for switching the connection among the data processors. A second acquisition module is configured to acquire setting data including a connectable range setting description for setting a connectable range that each connection selector can connect among the data processors. A setting module is configured to set the setting data to the first and second function descriptions.

### CROSS REFERENCE TO RELATED APPLICATION AND INCORPORATION BY REFERENCE

This application is based upon and claims the benefit of priority from prior Japanese Patent Application P2004-364960 filed on Dec. 16, 2004; the entire contents of which are incorporated by reference herein.

### BACKGROUND OF THE INVENTION

1. Field of the Invention

The present invention relates to technology for the automatic design of semiconductor integrated circuits, and more particularly to, an automatic design apparatus for semiconductor integrated circuits, a method for automatically designing semiconductor integrated circuits, and a computer-program product for executing an application of an automatic design apparatus for semiconductor integrated circuits.

2. Description of the Related Art

A field programmable gate array (FPGA) is known as a programmable circuit, and as possessing a reconfigurable circuit arrangement. The circuit arrangement of the FPGA can be reconfigured by configuration information stored in a configuration memory. Compared with the FPGA, reconfigurable processors can execute advanced data processing. The reconfigurable processor includes a plurality of data processors having circuit scale larger than data processors of the FPGA. The reconfigurable processor dynamically reconfigures the circuit arrangement in accordance with the configuration information, and operates as an image processor or a communications processor, for instance. Each data processor is arranged to be connectable to the other data processors. That is, a programmable circuit (reconfigurable processor) includes a plurality of connection selectors for reconfiguring the connection among the data processors. Furthermore, each connection selector includes a plurality of selectors. On the other hand, a technique that the user of a reconfigurable processor can select the processing bit width and the circuit arrangement of the data processors, in accordance with the use and the required performance, has been proposed.

However, despite a very high degree of versatility, the programmable circuit includes many circuit arrangements that are redundant for actual operation. Therefore, there are many cases where the circuit scale can be reduced by utilizing an application specific integrated circuit (ASIC), compared with utilizing the reconfigurable processor. Since the delay time and the power consumption increase in proportion to the circuit scale, a specification required by the user cannot be satisfied. Therefore, a reduction of the circuit scale of the connection selectors has been desired.

### SUMMARY OF THE INVENTION

An aspect of the present invention inheres in an automatic design apparatus for semiconductor integrated circuits encompassing, a first acquisition module configured to acquire a first function description describing an arrangement of a plurality of data processors, and a second function description describing an arrangement of a plurality of connection selectors for switching the connection among the data processors, a second acquisition module configured to acquire setting data including a connectable range setting description for setting a connectable range that each connection selector can connect among the data processors, and a setting module configured to set the setting data to the first and second function descriptions.

Another aspect of the present invention inheres in a method for automatically designing semiconductor integrated circuits encompassing, acquiring a first function description describing an arrangement of a plurality of data processors, and a second function description describing an arrangement of a plurality of connection selectors for switching the connection among the data processors, acquiring setting data including a connectable range setting description for setting a connectable range that each connection selector can connect among the data processors, and setting the setting data to the first and second function descriptions.

Still another aspect of the present invention inheres in a computer program product for executing an application for an automatic circuit design apparatus for semiconductor integrated circuits, the computer program product comprising, instructions configured to acquire a first function description describing an arrangement of a plurality of data processors, and a second function description describing an arrangement of a plurality of connection selectors for switching the connection among the data processors, instructions configured to acquire setting data including a connectable range setting description for setting a connectable range that each connection selector can connect among the data processors, and instructions configured to set the setting data to the first and second function descriptions.

### BRIEF DESCRIPTION OF THE DRAWINGS

FIG. 1 is a block diagram showing an automatic design apparatus according to an embodiment of the present invention.

FIG. 2 is a block diagram showing an example of a reconfigurable processor designed by the automatic design apparatus according to the embodiment.

FIG. 3 is a block diagram showing an example of a connection selector designed by the function of the automatic design apparatus according to the embodiment.

FIG. 4 is a block diagram showing an example of a reconfigurable processor designed by the automatic design apparatus according to the embodiment.

FIG. 5 is a block diagram showing an example of a connection selector designed by the function of the automatic design apparatus according to the embodiment.

FIG. 6 is a block diagram showing an example of a data processor designed by the automatic design apparatus according to the embodiment.

FIG. 7 is a flow chart showing a method for automatically designing semiconductor integrated circuits according to the embodiment.

FIG. 8 is a flow chart showing a method for automatically designing semiconductor integrated circuits according to a modification of the embodiment.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and description of the same or similar parts and elements will be omitted or simplified. In the following descriptions, numerous specific details are set forth such as specific signal values, etc. to provide a thorough understanding of the present invention. However, it will be obvious to those skilled in the art that the present invention may be practiced without such specific details. In other instances, well-known circuits have been shown in block diagram form in order not to obscure the present invention with unnecessary detail. In the following description, the words “connect” or “connected” define a state in which first and second elements are electrically connected to each other without regard to whether or not there is a physical connection between the elements.

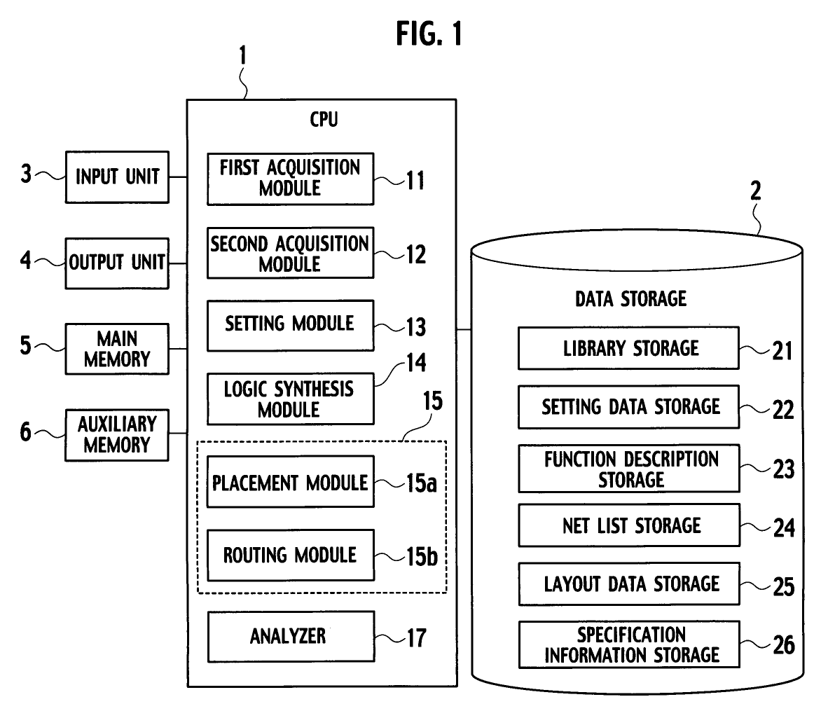

As shown in FIG. 1, an automatic design apparatus according to an embodiment of the present invention includes a central processing unit (CPU) 1, a data storage 2, an input unit 3, an output unit 4, a main memory 5, and an auxiliary memory 6. The data storage 2, the input unit 3, the output unit 4, the main memory 5, and the auxiliary memory 6 are connected to the CPU1. The CPU1 includes a first acquisition module 11, a second acquisition module 12, a setting module 13, a logic synthesis module 14, a layout generator 15, and an analyzer 17. The first acquisition module 11 acquires first and second function descriptions, the first function description defines an arrangement of a plurality of data processors, the second function description defines an arrangement of a plurality of connection selectors for switching the connection among the data processors. The “function description” refers to a logical expression described by hardware description language (HDL) in the stage of register transfer level (RTL) design, for instance. Or, a high level language, such as C language, can be utilized instead of the HDL. In this case, a high level synthesizer for converting the high level language into the HDL is included in the CPU 1. Furthermore, Perl language can be utilized instead of the HDL.

The second acquisition module 12 acquires setting data including a connectable range setting description for setting a connectable range that each connection selector can connect among the data processors. The setting module 13 sets the setting data to the first and second function descriptions.

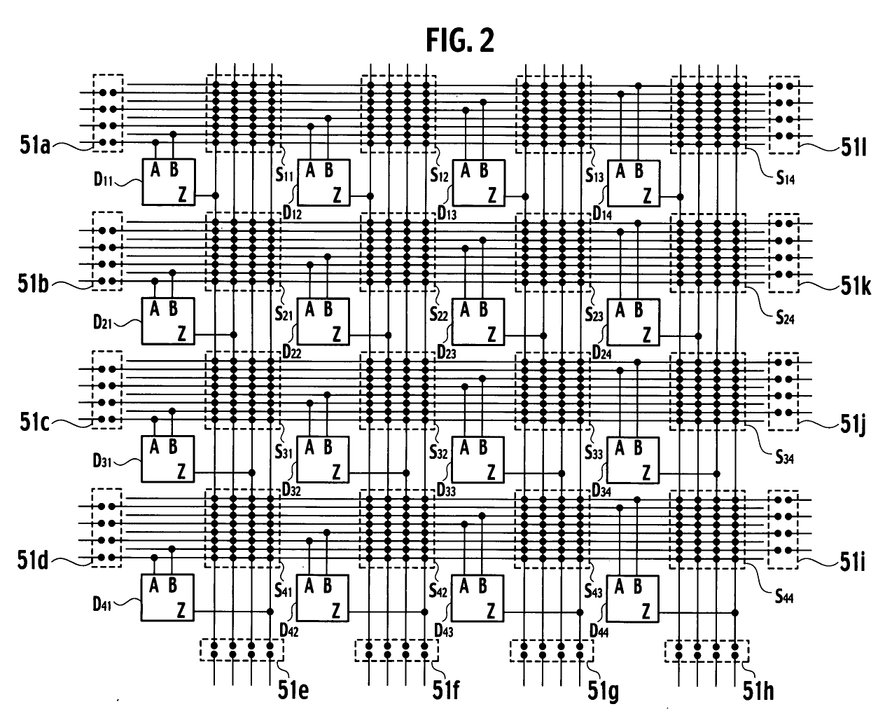

As shown in FIG. 2, the automatic design apparatus shown in FIG. 1 automatically designs the layout of a reconfigurable processor. The reconfigurable processor includes a plurality of connection selectors S₁₁ to S₄₄, and a plurality of data processors D₁₁ to D₄₄ placed in the state of matrix. The reconfigurable processor further includes a plurality of input/output (I/O) circuits 51a to 51l, in addition to the data processors D₁₁ to D₄₄ and connection selectors S₁₁ to S₄₄. The I/O circuits 51a to 51l are arranged such that the I/O circuits 51a to 51l surround the data processors D₁₁ to D₄₄ and connection selectors S₁₁ to S₄₄. The data processors D₁₁ to D₄₄, the connection selectors S₁₁ to S₄₄, and the I/O circuits 51a to 51l include configuration memories, and dynamically reconfigure the circuit arrangement in accordance with configuration information stored in the configuration memory. The I/O circuits 51a to 51l switch the connection between external devices and connection selectors S₁₁ to S₄₄.

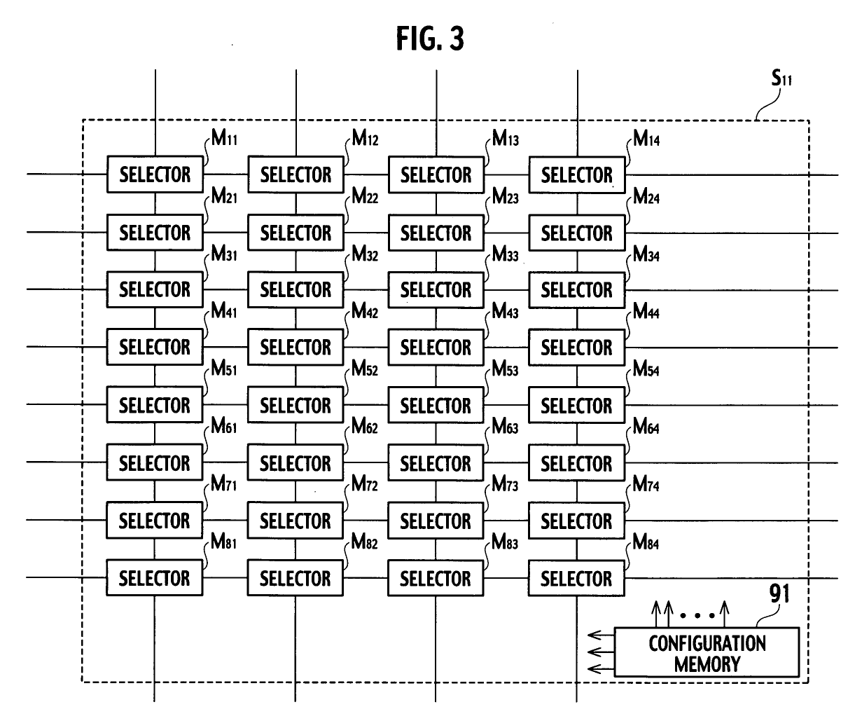

As shown in FIG. 3, the connection selector S11 includes a plurality of selectors M₁₁ to M₈₄, placed in the form of a matrix, and a configuration memory 91 connected to the selectors M₁₁ to M₈₄. The selectors M₁₁ to M₈₄ execute a selection of both the input data and the data output target, based on the configuration information stored in the configuration memory 91. The HDL description of the second function description for designing the connection selector S₁₁ shown in FIG. 2 and FIG. 3 is shown below.

module ConnectionNode (AorB,
Z00,Z01,Z02,Z03,Z10,Z11,Z12,Z13,Z20,Z21,Z22,Z23,Z30,Z31,Z32,Z33,
configurationC) ;
parameter P_DATASIZE = 15 ;
parameter P_CONNECTION_CFGSIZE = 4 ;
output [P_DATASIZE:0] AorB ;
input [P_DATASIZE:0]
Z00,Z01,Z02,Z03,Z10,Z11,Z12,Z13,Z20,Z21,Z22,Z23,Z30,Z31,Z32,Z33;
input [P_CONNECTION_CFGSIZE:0] configurationC ;
assign AorB =

fselinput(Z00,Z01,Z02,Z03,Z10,Z11,Z12,Z13,Z20,Z21,Z22,Z23,Z30,Z31,Z32,Z33,
configurationC) ;

function [P_DATASIZE:0] fselinput ;

input [P_DATASIZE:0]

Z00,Z01,Z02,Z03,Z10,Z11,Z12,Z13,Z20,Z21,Z22,Z23,Z30,Z31,Z32,Z33 ;

input [P_CONNECTION_CFGSIZE:0] configurationC ;
case (configurationC)

\grave{ }ifdef D_CONNECTION_DISTANCE0

| | |
|---|---|
| ′h0: fselinput = Z00 ; | ...(1) |

\grave{ }endif
\grave{ }ifdef D_CONNECTION_DISTANCE1

| | |
|---|---|
| ′h1: fselinput = Z01 ; | ...(2) |
| ′h2: fselinput = Z11 ; | ...(3) |
| ′h3: fselinput = Z10 ; | ...(4) |

\grave{ }endif
\grave{ }ifdef D_CONNECTION_DISTANCE2

| | |
|---|---|
| ′h4: fselinput = Z02 ; | ...(5) |
| ′h5: fselinput = Z12 ; | ...(6) |
| ′h6: fselinput = Z22 ; | ...(7) |
| ′h7: fselinput = Z21 ; | ...(8) |
| ′h8: fselinput = Z20 ; | ...(9) |

\grave{ }endif
\grave{ }ifdef D_CONNECTION_DISTANCE3

| | |
|---|---|
| ′h9: fselinput = Z03 ; | ...(10) |
| ′ha: fselinput = Z13 ; | ...(11) |
| ′hb: fselinput = Z23 ; | ...(12) |
| ′hc: fselinput = Z33 ; | ...(13) |
| ′hd: fselinput = Z32 ; | ...(14) |
| ′he: fselinput = Z31 ; | ...(15) |
| ′hf: fselinput = Z30 ; | ...(16) |

\grave{ }endif

default: fselinput = 16′hzzzz ;

endcase

endfunction

endmodule

Here, in the second function description, the connectable range is classified into four patterns from first to fourth patterns. That is, the connectable range setting description is set by a combination of the first to fourth patterns.

As shown in the expression (1), the description “ifdef D_CONNECTION_DISTANCE0” as the first pattern defines a specification connecting the inputs A and B to the own output Z of each data processor shown in FIG. 2.

As shown in the expressions (2) to (4), the description “′ifdef D_CONNECTION_DISTANCE1” as the second pattern defines a specification connecting the inputs A and B to the outputs Z of data processors surrounding each data processor. With respect to the data processor D11 shown in FIG. 2, the data processors D₁₂, D₂₁, and D₂₂ are selected by the expressions (2) to (4).

As shown in the expressions (5) to (9), the description “′ifdef D_CONNECTION_DISTANCE2” as the third pattern defines a specification connecting the inputs A and B to the outputs Z of data processors surrounding data processors selected by the second pattern. With respect to the data processor D11 shown in FIG. 2, the data processors D₁₃, D₂₃, D₃₃, D₃₂, and D₃₁ are selected by the expressions (5) to (9).

As shown in the expressions (10) to (16), the description “′ifdef D_CONNECTION_DISTANCE3” as the third pattern defines a specification connecting the inputs A and B to the outputs Z of data processors surrounding data processors selected by the third pattern. With respect to the data processor D11 shown in FIG. 2, the data processors D₁₄, D₂₄, D₃₄, D₄₄, D₄₃, D₄₂, and D₄₁ are selected by the expressions (10) to (16).

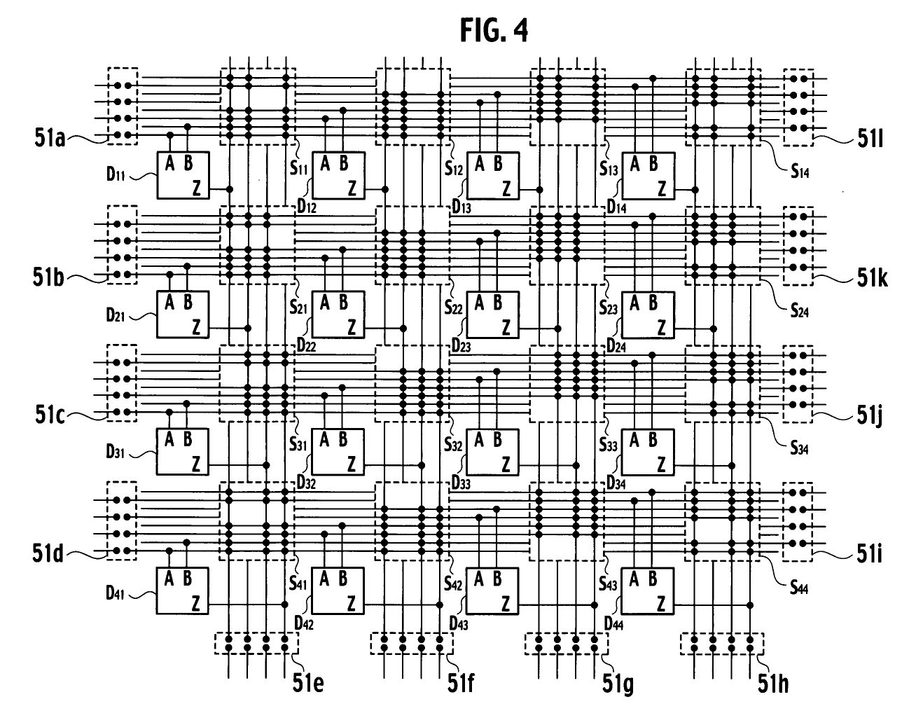

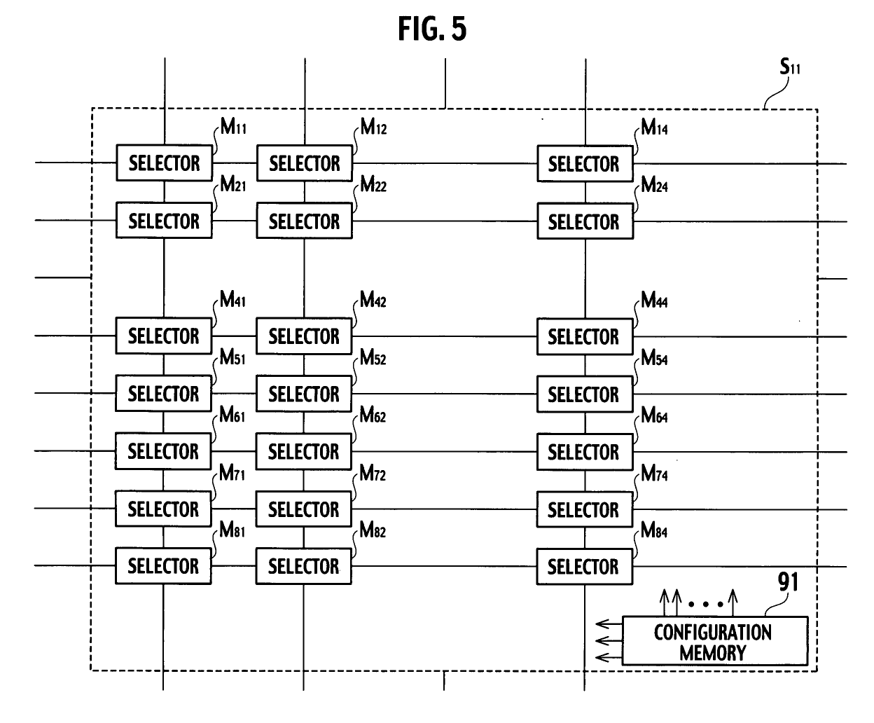

When the first pattern, the second pattern, and the fourth pattern are set as the connectable range, the number of selectors in each of connection selectors S₁₁ to S₄₄ is greatly decreased, as shown in FIG. 4. With respect to an example of FIG. 5, the number of selectors of the connection selector S₁₁ is reduced from 32 to 21, compared with FIG. 3.

The second acquisition module 12 shown in FIG. 1 further acquires both an internal circuit setting description and a bit width setting description from the data storage 2 as the setting data, in addition to the aforementioned connectable range setting description. The “internal circuit setting description” is utilized for setting the circuit arrangement of each internal circuit of the data processors D₁₁ to D₄₄ shown in FIG. 2. The “bit width setting description” is utilized for setting the bit width of data processed by the data processors D₁₁ to D₄₄, the connection selectors S₁₁ to S₄₄, and the I/O circuits 51a to 51l.

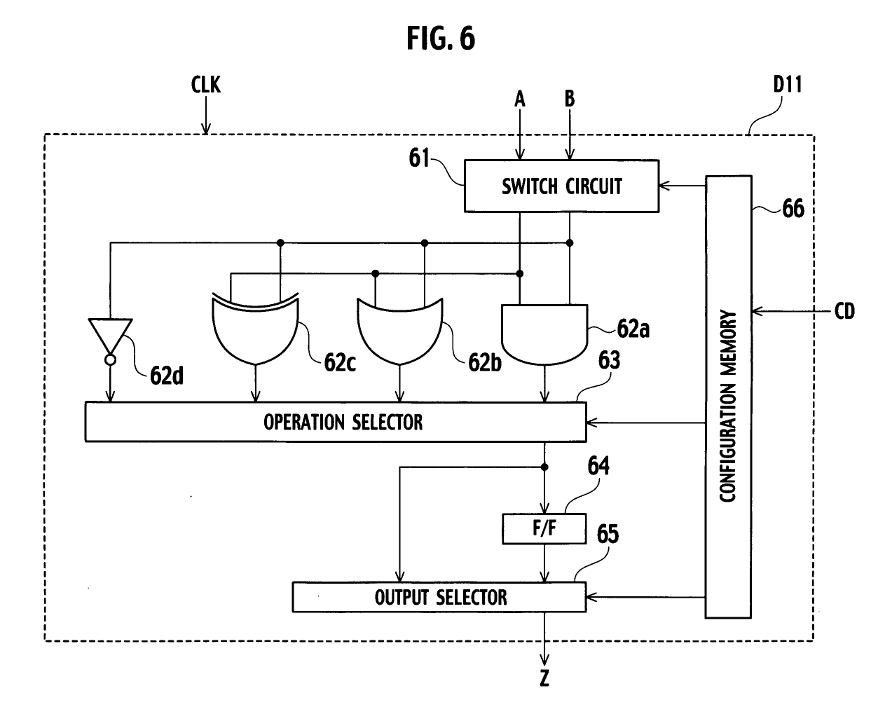

As shown in FIG. 6, the data processor DI1 includes a switch circuit 61, an AND circuit 62a, an OR circuit 62b, an exclusive OR (EOR) circuit 62c, an inverter 62d, an operation selector 63, flip-flop (F/F) 64, an output selector 65, and a configuration memory 66, for instance. The AND circuit 62a, the OR circuit 62b, the EOR circuit 62c, and the inverter 62d are connected between the switch circuit 61 and the operation selector 63. The F/F 64 is connected between the operation selector 63 and the output selector 65.

The switch circuit 61 transmits input data to one of the following in accordance with the configuration information: the AND circuit 62a, the OR circuit 62b, the EOR62c, and the inverter 62d. The operation selector 63 selects operation result of the AND circuit 62a, the OR circuit 62b, the EOR circuit 62c, and the inverter 62d in accordance with the configuration information. The F/F 64 stores output data of the operation selector 63 in synchronization with a clock CLK. The output selector 65 selects either the F/F 64 or the operation selector 63 in accordance with the configuration information.

The HDL description of the first function description for designing the data processor D₁₁ shown in FIG. 6 is shown below.

module DataProcessingNode (inputA, inputB, outputZ,
configurationD, clock) ;

parameter P_DATASIZE = 15 ;
parameter P_PROCESSING_CFGSIZE = 2 ;
input [P_DATASIZE:0] inputA ;
input [P_DATASIZE:0] inputB ;
output [P_DATASIZE:0] outputZ ;
input [P_PROCESSING_CFGSIZE:0] configurationD ;
input clock ;
wire [P_DATASIZE:0] candidateZw ;
reg [P_DATASIZE:0] candidateZr ;

\grave{ } ifdef D_PROCESSING_NOT

| | |
|---|---|
| wire [P_DATASIZE:0] candidateG = | •••••(17) |
| ˜ inputB ; | |

\grave{ }endif
\grave{ }ifdef D_PROCESSING_AND

| | |
|---|---|
| wire [P_DATASIZE:0] candidateH = | •••••(18) |
| inputA & inputB ; | |

\grave{ }endif
\grave{ }ifdef D_PROCESSING_OR

| | |
|---|---|
| wire [P_DATASIZE:0] candidateI = | •••••(19) |
| inputA \| inputB ; | |

\grave{ }endif
\grave{ }ifdef D_PROCESSING_XOR

| | |
|---|---|
| wire [P_DATASIZE:0] candidateJ = | •••••(20) |
| inputA \hat{ }inputB ; | |

\grave{ }endif
\grave{ }ifdef D_PROCESSING_EXT

wire [P_DATASIZE:0] candidateE =\grave{ }include
“DataProcessingNodeExtention.v”

•••••(21)
\grave{ }endif

assign outputZ = configurationD[0] ? candidateZr :
candidateZw ;
assign candidateZw =
fseloutput(candidateG,candidateH,candidateI,candidateJ,

\grave{ }ifdef D_PROCESSING_EXT
candidateE,
\grave{ }endif

configurationD[P_PROCESSING_CFGSIZE:1]) ;
function [P_DATASIZE:0] fseloutput ;

input [P_DATASIZE:0] candidateG ;
input [P_DATASIZE:0] candidateH ;
input [P_DATASIZE:0] candidateI ;
input [P_DATASIZE:0] candidateJ ;

\grave{ }ifdef D_PROCESSING_EXT

input [P_DATASIZE:0] candidateE ;

\grave{ }endif

input [P_PROCESSING_CFGSIZE-1:0] configurationD ;
case (configurationD)

′h0 : fseloutput = candidateG ;
′h1 : fseloutput = candidateH ;
′h2 : fseloutput = candidateI ;
′h3 : fseloutput = candidateJ ;

\grave{ }ifdef D_PROCESSING_EXT

default : fseloutput = candidateE ;

\grave{ }endif

endcase

endfunction
always @ (posedge clock) begin

candidateZr <= candidateZw ;

end

endmodule

The expression (17) defines the inverter 62d shown in FIG. 6. The expression (18) defines the AND circuit 62a. The expression (19) defines the OR circuit 62b. The expression (20) defines the EOR circuit 62c.

The internal circuit setting description selects required logic circuits from the AND circuit 62a, the OR circuit 62b, the EOR circuit 62c, and the inverter 62d. Logic circuits except the AND circuit 62a, the OR circuit 62b, the EOR circuit 62c, and the inverter 62d are added by the expression (21). For example a NAND circuit or a NOR circuit is added by the internal circuit setting description. The bit width setting description sets each bit width of the inputs A and B and the configuration information supplied by the configuration memory 66 to the switch circuit 61, the operation selector 63, and the output selector 65.

The first acquisition module 11 shown in FIG. 1 further acquires a third function description defining the arrangement of the I/O circuits 51a to 51l shown in FIG. 2, and a fourth function description for combining the first to third function descriptions, from the data storage 2.

The logic synthesis module 14 generates a net list, by executing a logic synthesis to first to fourth function descriptions to which the setting data has been set. The analyzer 17 analyzes the generated net list. Specifically, the analyzer 17 estimates the operational speed and the circuit scale of the layout after executing placement and routing processing, based on the generated net list. Then, the analyzer 17 compares the estimation result with the specification, and determines whether the specification is satisfied.

The layout generator 15 includes a placement module 15a configured to execute the placement processing to the generated net list, and a routing module 15b configured to execute the routing processing.

The data storage 2 includes a library storage 21, a setting data storage 22, a function description storage 23, a net list storage 24, a layout data storage 25, and a specification information storage 26. The library storage 21 stores the first to fourth function descriptions. The setting data storage 22 stores the setting data. The function description storage 23 stores the first to fourth function descriptions to which the setting data is set. The net list storage 24 stores the net list. The layout data storage 25 stores the layout data. The specification information storage 26 stores the specification information.

It should be noted that the CPU 1 includes a database manager and an input/output manager which are not shown in the drawing. Moreover, when an input to or an output from the data storage 3 is required, a search for the storage location of a necessary file is conducted by use of the database manager and reading and writing of the file is thereby performed. On the other hand, when an input to or an output from the CPU 1 is required, a file is inputted from the input unit 3 or a file is outputted to the output unit 4, the auxiliary memory 6 or the like by use of the input/output manager. Here, the data storage 2 may be included with the auxiliary memory 6 when appropriate.

The input unit 3 may be a keyboard, a mouse or an authentication unit, such as an optical character reader (OCR), a graphic input unit such as an image scanner, and a special input unit such as a voice recognition device. The output unit 4 may be a display unit such as a liquid crystal display or a cathode-ray tube (CRT) display, a printer such as an ink-jet printer or a laser printer, and the like. The input/output manager (an input/output interface, not illustrated) is provided as an interface for connecting the input unit 3, the output unit 4, the auxiliary memory 6, a reader for a memory unit such as a compact disk-read only memory (CD-ROM), a magneto-optical (MO) disk or a flexible disk, or the like to CPU 1. From a data flow viewpoint, the input/output controller is the interface for the input unit 3, the output unit 4, the auxiliary memory 6 or the reader for the external memory unit with the main memory 5. The main memory 5 includes a read only memory (ROM) and a random access memory (RAM). The ROM works as a program memory unit or the like which stores a program to be executed by the CPU 1. The RAM temporarily stores the program for the CPU 1 and data which are used during execution of the program, and also works as a temporary data memory used as a work area.

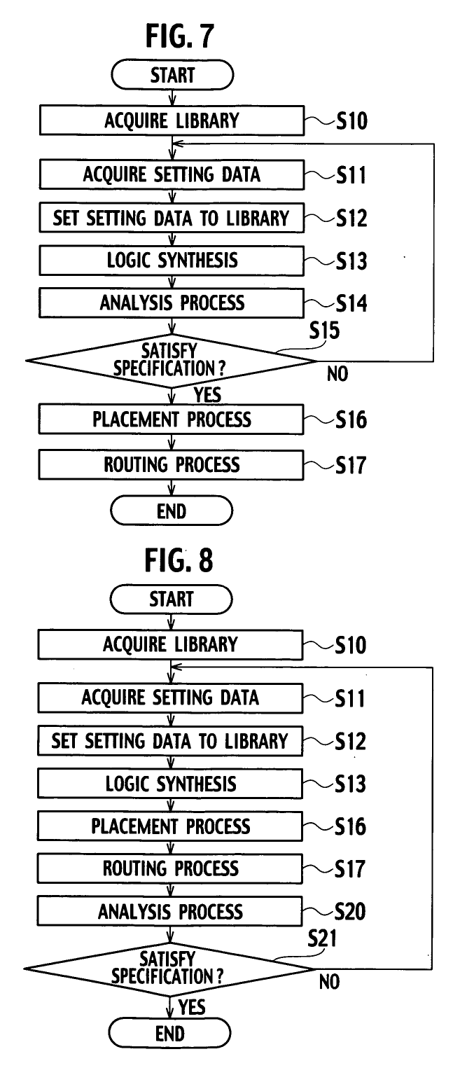

Next, a method for automatically designing semiconductor integrated circuits according to the embodiment of the present invention will be described referring to a flowchart shown in FIG. 7. An example that the automatic design apparatus shown in FIG. 1 designs the layout of the reconfigurable processor shown in FIG. 4 will be described.

In step S10, the first acquisition module 11 shown in FIG. 1 acquires the library, i.e., the first to fourth function descriptions from the library storage 21.

In step S11, the second acquisition module 12 acquires setting data, i.e., the connectable range setting description, the internal circuit setting description, and the bit width setting description from the setting data storage 22. The step S11 may be executed before the step 10.

In step S12, the second acquisition module 12 sets the setting data acquired in the step 11 to the library acquired in the step S10. The first to fourth function descriptions to which the setting data is set are stored in the function description storage 23.

In step S13, the logic synthesis module 14 generates a net list by executing a logic synthesis to first to fourth function descriptions to which the setting data has been set. The generated net list is stored in the net list storage 24.

In step S14, analyzes the net list generated in step 13. The analyzer 17 acquires the specification information from the specification information storage 26, and determines whether the specification is satisfied. When it is determined that the specification is satisfied, the procedure goes to step S16. When it is determined that the specification is not satisfied, the procedure returns to step S11. In this case, the second acquisition module 12 acquires setting data different from the last acquired setting data, from the setting data storage 22.

In step S16, the placement module 15a executes the placement process to the analyzed net list. Specifically, the data processors D₁₁ to D₄₄, the connection selectors S₁₁ to S₄₄, and the I/O circuits 51a to 51l shown in FIG. 4 are placed on a virtual chip imitating an actual chip.

In step S17, the routing module 15b executes a routing process to the data processors D₁₁ to D₄₄, the connection selectors S₁₁ to S₄₄, and the I/O circuits 51a to 51l placed on the virtual chip. As a result, the layout data is generated, and the generated layout is stored in the layout data storage 25.

As described above, according to the embodiment of the present invention, it is possible to control the number of selectors in each connection selector when the setting module 13 sets the connectable range setting description to the second function description. Moreover, it is possible to change the arrangement of the connection selectors and the data processors, in accordance with the use and the required performance. Therefore, it is possible to reduce the circuit scale of entire reconfigurable processor, and to improve the operational speed and the power consumption.

(Modification)

As a modification of the embodiment, the analyzer 17 of FIG. 1 may analyze layout data after the placement and routing processing of step S16 and step S17, as shown in FIG. 8. That is, the analyzer 17 analyzes the layout data stored in the layout data storage 25 without analyzing the net list stored in the net list storage 24. It is possible to improve the precision of the analysis by analyzing the layout data, compared with analyzing the net list. Furthermore, the analyzer 17 may execute the analysis processing to the function description stored in the function description storage 23. In this case, it is possible to early determine whether the specification is satisfied.

### OTHER EMBODIMENTS

Various modifications will become possible for those skilled in the art after receiving the teachings of the present disclosure without departing from the scope thereof.

In the aforementioned embodiment, an example in which the automatic design apparatus automatically designs the data processors D₁₁ to D₄₄, the connection selectors S₁₁ to S₄₄, and I/O circuits 51a to 51l is disclosed. However, the automatic design apparatus may automatically design peripheral circuits of the reconfigurable processor, such as a micro processing unit or a cache memory.

The constitution that data processors are arranged in the form of a matrix has been explained. However, data processors may be arranged in the form of a hypercube, a straight line, or a tree. Furthermore, the automatic design apparatus according to the embodiment may be applied to various programmable circuits, such as a FPGA, without limiting to the reconfigurable processor.

In the embodiment, the connectable range capable of connecting among the data processors is classified into four patterns. However, when each data processor and each connection selector are independently defined, it is possible to increase the variation of the connectable range.

The automatic design apparatus according to the embodiment may acquire data, such as the first to fourth function descriptions, the setting data, and the specification information, via a network.

What is claimed is:

1. An automatic design apparatus for semiconductor integrated circuits comprising:
a first acquisition module configured to acquire a first function description describing an arrangement of a plurality of data processors, and a second function description describing an arrangement of a plurality of connection selectors for switching the connection among the data processors;
a second acquisition module configured to acquire setting data including a connectable range setting description for setting a connectable range that each connection selector can connect among the data processors; and
a setting module configured to set the setting data to the first and second function descriptions.

2. The automatic design apparatus of claim 1, wherein the setting data further includes an internal circuit setting description for setting an arrangement of an internal circuit of each data processor, and a bit width setting description for setting a bit width of data processed by each data processor.

3. The automatic design apparatus of claim 2, wherein the setting module further sets the internal circuit setting description and the bit width setting description to the first function description.

4. The automatic design apparatus of claim 1, further comprising:
a logic synthesis module configured to execute a logic synthesis to the first and second function descriptions to net list;
a layout generator configured to generate layout data of the data processors and the connection selectors, based on the net list; and
an analyzer configured to analyze one of the first and second function descriptions to which the setting data is set, the net list, and the layout data.

5. The automatic design apparatus of claim 4, wherein the second acquisition module acquires the setting data, based on an analysis result of the analyzer.

6. The automatic design apparatus of claim 1, wherein the connectable range setting description is described such that the connectable range is classified into a plurality of patterns.

7. The automatic design apparatus of claim 1, wherein the semiconductor integrated circuit to be designed is a programmable circuit integrated on a semiconductor chip.

8. A method for automatically designing semiconductor integrated circuits comprising:
acquiring a first function description describing an arrangement of a plurality of data processors, and a second function description describing an arrangement of a plurality of connection selectors for switching the connection among the data processors;
acquiring setting data including a connectable range setting description for setting a connectable range that each connection selector can connect among the data processors; and
setting the setting data to the first and second function descriptions.

9. The method of claim 8, wherein the setting data further includes an internal circuit setting description for setting an arrangement of an internal circuit of each data processor, and a bit width setting description for setting a bit width of data processed by each data processor.

10. The method of claim 9, further comprising setting the internal circuit setting description and the bit width setting description to the first function description.

11. The method of claim 8, further comprising:
executing a logic synthesis to the first and second function descriptions to which the setting data is set;
generating layout data of the data processors and the connection selectors, based on the net list; and
analyzing one of the first and second function descriptions to which the setting data is set, the net list, and the layout data.

12. The method of claim 11, further comprising acquiring the setting data, based on an analysis result by analyzing one of the first and second function descriptions to which the setting data is set, the net list, and the layout data.

13. The method of claim 8, wherein the connectable range setting description is described such that the connectable range is classified into a plurality of patterns.

14. The method of claim 8, wherein the semiconductor integrated circuit to be designed is a programmable circuit integrated on a semiconductor chip.

15. A computer program product for executing an application for an automatic circuit design apparatus for semiconductor integrated circuits, the computer program product comprising:
instructions configured to acquire a first function description describing an arrangement of a plurality of data processors, and a second function description describing an arrangement of a plurality of connection selectors for switching the connection among the data processors;
instructions configured to acquire setting data including a connectable range setting description for setting a connectable range that each connection selector can connect among the data processors; and
instructions configured to set the setting data to the first and second function descriptions.

16. The computer program product of claim 15, wherein the setting data further includes an internal circuit setting description for setting an arrangement of an internal circuit of each data processor, and a bit width setting description for setting a bit width of data processed by each data processor.

17. The computer program product of claim 16, further comprising instructions configured to set the internal circuit setting description and the bit width setting description to the first function description.

18. The computer program product of claim 15, further comprising:
instructions configured to execute a logic synthesis to the first and second function descriptions to which the setting data is set;
instructions configured to generate layout data of the data processors and the connection selectors, based on the net list; and
instructions configured to analyze one of the first and second function descriptions to which the setting data is set, the net list, and the layout data.

19. The computer program product of claim 18, further comprising instructions configured to acquire the setting data, based on an analysis result of the instructions configured to analyze.

20. The computer program product of claim 15, wherein the connectable range setting description is described such that the connectable range is classified into a plurality of patterns.
